(19) United States
(12) Patent Application Publication
(10) Pub. No.: US 2025/0040159 A1
(43) Pub. Date: Jan. 30, 2025

(54) METAL-INSULATOR-METAL CAPACITOR STRUCTURE AND METHOD FORM FORMING SAME

(71) Applicant: SEMICONDUCTOR MANUFACTURING INTERNATIONAL (SHANGHAI) CORPORATION, Shanghai (CN)

(72) Inventor: Jisong JIN, Shanghai (CN)

(73) Assignee: SEMICONDUCTOR MANUFACTURING INTERNATIONAL (SHANGHAI) CORPORATION, Shanghai (CN)

(21) Appl. No.: 18/784,142

(22) Filed: Jul. 25, 2024

(30) Foreign Application Priority Data
Jul. 26, 2023 (CN) 202310932388.8

(51) Int. Cl. H01G 4/30; H01L 23/522

(52) U.S. Cl. CPC H01L 28/60; H01L 23/5223

(57) ABSTRACT

This disclosure relates to a metal-insulator-metal capacitor structure and a method for forming the same. The metal-insulator-metal capacitor structure includes: a first capacitor dielectric layer, located on a first electrode layer; a second electrode layer, located on the first capacitor dielectric layer in a first capacitor region; and one or more capacitor stacks, located on the second electrode layer in the first capacitor region. Each of the capacitor stacks includes a second capacitor dielectric layer and a third electrode layer located on the second capacitor dielectric layer. Projection overlay regions exist between the third electrode layer and the second electrode layer and between the adjacent third electrode layers. The one or more second capacitor dielectric layers are further located on the first capacitor dielectric layer in the second capacitor region disclosure.

### CROSS REFERENCE TO RELATED APPLICATIONS

This application is based on and claims priority to Chinese Patent Application No. 202310932388.8, filed on Jul. 26, 2023, the entire content of which is incorporated herein by reference.

### TECHNICAL FIELD

The present disclosure relates to the field of semiconductor manufacturing, and in particular to a metal-insulator-metal capacitor structure and a method for forming the metal-insulator-metal capacitor structure.

### BACKGROUND

The semiconductor integrated circuit (IC) industry has experienced rapid growth. Technological advances in materials and design in the IC industry have produced generations of ICs. Each generation has smaller and more complex circuits than the previous generation. However, these advances have increased the complexity of processing and manufacturing of ICs. In order to realize these advances, similar developments are needed in the processing and manufacturing of ICs. During the development of ICs, the functional density (i.e., the number of interconnect devices per chip area) has gradually increased, while the geometric size (i.e., the smallest component that can be manufactured using the manufacturing process) has gradually decreased.

One type of capacitor is a metal insulator metal (MIM) capacitor, which is usually used in mixed signal devices and logic devices (such as embedded memories and radio frequency devices). The MIM capacitor is usually used for storing charges in various semiconductor devices. In order to meet the performance requirements of devices, the capacitance density of the MIM capacitor is gradually increasing.

However, when the MIM capacitor capacitance density increases, the equivalent oxide thickness (EOT) of dielectric layer of MIM between two metal plate will decrease which leads to lower break down voltage of MIM capacitor and the normal operation voltage of MIM capacitor also have to be lowered. However in current semiconductor manufactory industry usually one MIM capacitor can only support a maximum voltage like 1.8V or 1.5V. Beyond the maximum voltage the reliability of MIM capacitor could not be warranted. But normally in IC design point of view, MIM capacitor better supports wider range of voltage, or could support as high voltage as possible while still keeping high capacitance density. So the performance of current MIM capacitor still needs to be improved.

### SUMMARY

The present disclosure relates to a metal-insulator-metal capacitor structure and a method for forming the same to optimize the performance of the metal-insulator-metal capacitor structure.

In an aspect of the disclosure, a metal-insulator-metal capacitor structure is provided. The metal-insulator-metal capacitor structure may include: a substrate, including a first capacitor region and a second capacitor region; a plurality of first electrode layers, respectively located on the substrate in the first capacitor region and the second capacitor region; a first capacitor dielectric layer, located on the first electrode layer; a second electrode layer, located on the first capacitor dielectric layer in the first capacitor region; and one or more capacitor stacks, located on the second electrode layer in the first capacitor region. Each of the capacitor stacks includes a second capacitor dielectric layer and a third electrode layer located on the second capacitor dielectric layer. Projection overlay regions exist between the third electrode layer and the second electrode layer and between adjacent third electrode layers. The one or more second capacitor dielectric layers are further located on the first capacitor dielectric layer in the second capacitor region. The third electrode layer at a top of in the capacitor stack is used as a top electrode layer. The top electrode layer is further located on the one or more second capacitor dielectric layers in the second capacitor region, and a projection overlay region exists between the top electrode layer and the first electrode layer.

In another aspect of the disclosure, a method for forming a metal-insulator-metal capacitor structure is provided. The method may include: providing a substrate including a first capacitor region and a second capacitor region; forming a plurality of first electrode layers, which are respectively located in the first capacitor region and the second capacitor region, on the substrate; forming a first capacitor dielectric layer on the first electrode layer; forming a second electrode layer on the first capacitor dielectric layer in the first capacitor region; and forming one or more capacitor stacks in the first capacitor region after the second electrode layer is formed, wherein each of the capacitor stacks includes a second capacitor dielectric layer and a third electrode layer located on the second capacitor dielectric layer, and projection overlay regions exists between the third electrode layer and the second electrode layer and between the adjacent third electrode layers. In the step of forming a second capacitor dielectric layer, one or more second capacitor dielectric layers are further formed on the first capacitor dielectric layer in the second capacitor region. The third electrode layer at a top of the capacitor stack is used as a top electrode layer. The top electrode layer is further formed on the one or more second capacitor dielectric layers in the second capacitor region, and a projection overlay region exists between the top electrode layer and the first electrode layer.

Compared with the prior art, the implementations of the present disclosure have the following advantages:

In the metal-insulator-metal capacitor structure provided by the implementation of the present disclosure, the one or more capacitor stacks located on the second electrode layer in the first capacitor region are further arranged. Each of the capacitor stacks includes the second capacitor dielectric layer and the third electrode layer located on the second capacitor dielectric layer. The projection overlay regions exist between the third electrode layer and the second electrode layer and between the adjacent third electrode layers. The one or more second capacitor dielectric layers are further located on the first capacitor dielectric layer in the second capacitor region. The third electrode layer in the capacitor stack at the top is used as the top electrode layer. The top electrode layer is further located on the one or more second capacitor dielectric layers in the second capacitor region, and there exists the projection overlay region between the top electrode layer and the first electrode layer. Therefore, in the first capacitor region, the one or more capacitor stacks are further arranged on the second electrode layer, so that capacitors can be formed between the adjacent electrode layers (between the first electrode layer and the second electrode layer, between the second electrode layer and the third electrode layer, and between the adjacent third electrode layers), which is beneficial to improving the capacitance density of the first capacitor region. In the second capacitor region, a capacitor is formed between the first electrode layer and the top electrode layer, and the first capacitor dielectric layer and the one or more second capacitor dielectric layers are arranged between the first electrode layer and the top electrode layer, which increases the thickness of the capacitor dielectric layer between the first electrode layer and the top electrode layer, thereby improving the voltage resistance of the capacitor in the second capacitor region. Thereby, in this implementation of the present disclosure, not only the capacitors with good voltage resistance, but also the capacitors with high capacitance density can be formed, thereby meeting the requirements of providing capacitors with different types and performance parameters on the substrate.

In the method for forming a metal-insulator-metal capacitor structure, the one or more capacitor stacks are further formed in the first capacitor region after the second electrode layer is formed. Each of the capacitor stacks includes the second capacitor dielectric layer and the third electrode layer located on the second capacitor dielectric layer. The projection overlay regions exist between the third electrode layer and the second electrode layer and between the adjacent third electrode layers. In the step of forming the second capacitor dielectric layer, the one or more second capacitor dielectric layers are further formed on the first capacitor dielectric layer in the second capacitor region. The third electrode layer in the capacitor stack at the top is used as the top electrode layer. The top electrode layer is further formed on the one or more second capacitor dielectric layers in the second capacitor region, and there exists the projection overlay region between the top electrode layer and the first electrode layer. Therefore, in the first capacitor region, the one or more capacitor stacks are further formed on the second electrode layer, so that capacitors can be formed between the adjacent electrode layers (between the first electrode layer and the second electrode layer, between the second electrode layer and the third electrode layer, and between the adjacent third electrode layers), which is beneficial to improving the capacitance density of the first capacitor region. In the second capacitor region, a capacitor is formed between the first electrode layer and the top electrode layer, and the first capacitor dielectric layer and the one or more second capacitor dielectric layers are formed between the first electrode layer and the top electrode layer, which increases the thickness of the capacitor dielectric layer between the first electrode layer and the top electrode layer, thereby improving the voltage resistance of the capacitor in the second capacitor region. Thereby, in this implementation of the disclosure, not only the capacitors with good voltage resistance, but also the capacitors with high capacitance density can be formed, thereby meeting the requirements of providing capacitors with different types and performance parameters on the substrate.

### BRIEF DESCRIPTION OF THE DRAWINGS

FIG. 1 is a schematic structural view of a metal-insulator-metal capacitor structure according to an implementation of the present disclosure; and

FIG. 2 to FIG. 7 are schematic structural views corresponding to steps of a method for forming a metal-insulator-metal capacitor structure according to an implementation of the present disclosure.

### DETAILED DESCRIPTION

As discussed in the BACKGROUND, the performance of the current metal-insulator-metal capacitor structures still needs to be improved.

In order to address the technical problems, an implementation of the present disclosure provides a metal-insulator-metal capacitor structure. One or more capacitor stacks located on a second electrode layer in a first capacitor region are further arranged. Each of the capacitor stacks includes a second capacitor dielectric layer and a third electrode layer located on the second capacitor dielectric layer. There exist projection overlay regions between the third electrode layer and the second electrode layer and between the adjacent third electrode layers. The one or more second capacitor dielectric layers are further located on a first capacitor dielectric layer in a second capacitor region. The third electrode layer in the capacitor stack at a top is used as a top electrode layer. The top electrode layer is further located on the one or more second capacitor dielectric layers in the second capacitor region, and there exists a projection overlay region between the top electrode layer and the first electrode layer. Therefore, in the first capacitor region, the one or more capacitor stacks are further arranged on the second electrode layer, so that capacitors can be formed between the adjacent electrode layers (between the first electrode layer and the second electrode layer, between the second electrode layer and the third electrode layer, and between the adjacent third electrode layers), which is beneficial to improving the capacitance density of the first capacitor region. In the second capacitor region, a capacitor is formed between the first electrode layer and the top electrode layer, and the first capacitor dielectric layer and the one or more second capacitor dielectric layers are arranged between the first electrode layer and the top electrode layer, which increases the thickness of the capacitor dielectric layer between the first electrode layer and the top electrode layer, thereby improving the voltage resistance of the capacitor in the second capacitor region. Thereby, in this implementation of the present disclosure, not only the capacitors with good voltage resistance, but also the capacitors with high capacitance density can be formed, thereby meeting the requirements of providing capacitors with different types and performance parameters on the substrate.

In order to address the technical problems, an implementation of the present disclosure further provides a method for forming a metal-insulator-metal capacitor structure. The one or more capacitor stacks are further formed in the first capacitor region after the second electrode layer is formed. Each of the capacitor stacks includes the second capacitor dielectric layer and the third electrode layer located on the second capacitor dielectric layer. There exist the projection overlay regions between the third electrode layer and the second electrode layer and between the adjacent third electrode layers. In the step of forming the second capacitor dielectric layer, the one or more second capacitor dielectric layers are further formed on the first capacitor dielectric layer in the second capacitor region. The third electrode layer in the capacitor stack at the top is used as the top electrode layer. The top electrode layer is further formed on the one or more second capacitor dielectric layers in the second capacitor region, and there exists the projection overlay region between the top electrode layer and the first electrode layer. Therefore, in the first capacitor region, the one or more capacitor stacks are further formed on the second electrode layer, so that capacitors can be formed between the adjacent electrode layers (between the first electrode layer and the second electrode layer, between the second electrode layer and the third electrode layer, and between the adjacent third electrode layers), which is beneficial to improving the capacitance density of the first capacitor region. In the second capacitor region, a capacitor is formed between the first electrode layer and the top electrode layer, and the first capacitor dielectric layer and the one or more second capacitor dielectric layers are formed between the first electrode layer and the top electrode layer, which increases the thickness of the capacitor dielectric layer between the first electrode layer and the top electrode layer, thereby improving the voltage resistance of the capacitor in the second capacitor region. Thereby, in this implementation of the form disclosure, not only the capacitors with good voltage resistance, but also the capacitors with high capacitance density can be formed, thereby meeting the requirements of providing capacitors with different types and performance parameters on the substrate.

To make the foregoing objectives, features, and advantages of the implementations of the present disclosure clearer and easier to understand, specific implementations of the present disclosure are described in detail below with reference to the accompanying drawings.

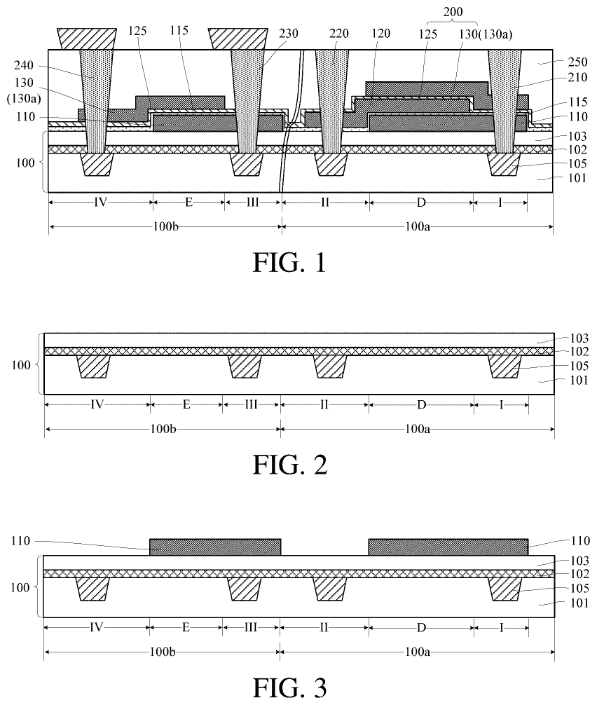

Referring to FIG. 1, which shows a schematic structural view of a metal-insulator-metal capacitor structure according to an implementation of the present disclosure.

As shown in FIG. 1, in this implementation, the metal-insulator-metal capacitor structure includes: a substrate 100, including a first capacitor region 100a and a second capacitor region 100b; a plurality of first electrode layers 110, respectively located on the substrate in the first capacitor region 100a and the second capacitor region 100b; a first capacitor dielectric layer 115, located on the first electrode layer 110; a second electrode layer 120, located on the first capacitor dielectric layer 115 in the first capacitor region 100a; and one or more capacitor stacks 200, located on the second electrode layer 120 in the first capacitor region 100a. Each of the capacitor stacks 200 includes a second capacitor dielectric layer 125 and a third electrode layer 130 located on the second capacitor dielectric layer 125. There exist projection overlay regions D between the third electrode layer 130 and the second electrode layer 120 and between the adjacent third electrode layers 130. The one or more second capacitor dielectric layers 125 are further located on the first capacitor dielectric layer 115 in the second capacitor region 100b. The third electrode layer 130 in the capacitor stack 200 at a top is used as a top electrode layer 130a. The top electrode layer 130a is further located on the one or more second capacitor dielectric layers 125 in the second capacitor region 100b, and there exists a projection overlay region E between the top electrode layer and the first electrode layer 110.

The substrate 100 is used for providing a process platform for forming an MIM capacitor.

In this implementation, the substrate 100 includes a device structure layer (not shown) and a back-end-of-line interconnect layer (not shown) located on the device structure layer and electrically connected to the device structure layer. The back-end-of-line interconnect layer includes a bottom dielectric layer 101 and one or more metal layers located in the bottom dielectric layer, and the plurality of metal layers located at a top are used as top metal layers 105.

The device structure layer is formed by a front-end-of-line device manufacturing process. In specific implementation, the device structure layer may include a substrate and device structures located on the substrate. The device structures may include MOS transistors and the like, such as NMOS transistors and PMOS transistors.

In an example, the substrate is a silicon substrate. In other implementations, a material of the substrate may also be germanium, silicon germanide, silicon carbide, gallium arsenide, indium gallide or the like, and the substrate may also be a silicon-on-insulator substrate, a germanium-on-insulator substrate or other types of substrates.

The back-end-of-line interconnect layer is formed by a back-end-of-line interconnect process.

In this implementation, the back-end-of-line interconnect layer includes the bottom dielectric layer 101 and the one or more metal layers located in the bottom dielectric layer 101, and the plurality of metal layers located at the top are used as the top metal layers 105.

The bottom dielectric layer 101 is used for isolating the metal layers. Specifically, the bottom dielectric layer 101 is an inter metal dielectric (IMD) layer.

A material of the bottom dielectric layer 101 is a dielectric material. In an example, the material of the bottom dielectric layer 101 is silicon oxide.

In this implementation, the adjacent metal layers are electrically connected to each other so as to electrically lead out the device structures in the device structure layer through the one or more metal layers. Specifically, the two adjacent metal layers are electrically connected through a via interconnect structure located therebetween. The device structures in the device structure layer are electrically led out through the top metal layers 105.

A material of the metal layers is a conductive material. In this implementation, the material of the metal layers includes one or more of W, Cu, Co, TiN, Ti, Ta, TaN, Ru, RuN and Al.

The first capacitor region 100a and the second capacitor region 100b are respectively used for forming capacitors. Specifically, in this implementation, capacitors with different types and performance parameters are respectively formed in the first capacitor region 100a and the second capacitor region 100b.

In this implementation, the substrate 100 further includes: an etch stop layer 102, located on the bottom dielectric layer 101 and covering the top metal layer 105; and a top dielectric layer 103, located on the etch stop layer 102.

The etch stop layer 102 is used for defining an etch stop position in the steps of forming the first conductive plug, the second conductive plug, the third conductive plug and the fourth conductive plug, which reduces the damage to the top metal layer 105 and is beneficial to improving the consistency of heights of bottoms of the first conductive plug, the second conductive plug, the third conductive plug and the fourth conductive plug.

In an example, a material of the etch stop layer 102 is silicon nitride. In other implementations, the material of the etch stop layer may also be other materials that have high etch selectivity with the substrate material, for example, one or more of silicon nitride, aluminum oxide, aluminum nitride and NDC (nitride doped carbon).

The top dielectric layer 103 is used for isolating the top metal layer 105 and the first electrode layer 110.

A material of the top dielectric layer 103 is a dielectric material. In an example, the material of the top dielectric layer 103 is silicon oxide.

The first electrode layer 110 is used as a plate electrode of the MIM capacitor.

In this implementation, the second electrode layer 120 exposes a part of a top of the first electrode layer 110. In the first capacitor region 100a, the part of the top of the first electrode layer 110 exposed by the second electrode layer 120 is used as a first connection region I. In the second capacitor region 100b, the top electrode layer 130a exposes a part of a top of the first electrode layer 110, and the part of the top of the first electrode layer 110 exposed by the top electrode layer 130a is used as a third connection region III.

In this implementation, in the first capacitor region 100a, the first connection region I is used for forming the first conductive plug, so that the first conductive plug is electrically connected to the first electrode layer 110 or the first conductive plug is electrically connected to the first electrode layer 110 and the odd-numbered third electrode layers 130.

In this implementation, in the second capacitor region 100b, the third connection region III is used for forming the third conductive plug, so that the third conductive plug is electrically connected to the first electrode layer 110.

A material of the first electrode layer 110 is a conductive material. In an example, the material of the first electrode layer 110 includes one or more of W, Cu, Co, TiN, Ti, Ta, TaN, Ru, RuN and Al.

The first capacitor dielectric layer 115 is used as an insulating layer in the MIM capacitor. The first capacitor dielectric layer 115 located in the first capacitor region 100a is used for isolating the first electrode layer 110 and the second electrode layer 120. The first capacitor dielectric layer 115 located in the second capacitor region 100b is used for isolating the first electrode layer 110 and the top electrode layer 130a together with the second capacitor dielectric layer 125. Specifically, the first capacitor dielectric layer 115 conformally covers the first electrode layer 110 and the substrate 100.

A material of the first capacitor dielectric layer 115 is an insulating dielectric material. In this implementation, the material of the first capacitor dielectric layer 115 is a high k dielectric material. The high k dielectric material is a dielectric material with a relative dielectric constant greater than a relative dielectric constant of the silicon oxide. The use of the high k dielectric material is beneficial to increasing the capacitance value of the MIM capacitor and the capacitance density accordingly.

In an example, the material of the first capacitor dielectric layer 115 includes one or more of HfO₂, HfSiO, TiO₂, HfZrO, HfSiON, HfTaO, HfTiO, Ta₂O₅, ZrO₂, ZrSiO₂, Al₂O₃, SrTiO₃, BaSrTiO and SiN.

The second electrode layer 120 is used as a plate electrode of the MIM capacitor.

In this implementation, the second electrode layer 120 is further located on the substrate 100 on a side of the first electrode layer 110, and the part of the second electrode layer 120 located on the substrate 100 on the side of the first electrode layer 110 is used as a second connection region II.

In this implementation, in the first capacitor region 100a, the second connection region II is used for forming the second conductive plug, so that the second conductive plug is electrically connected to the second electrode layer 120, or to the second electrode layer 120 and the even-numbered third electrode layers 130.

A material of the second electrode layer 120 is a conductive material. In an example, the material of the second electrode layer 120 includes one or more of W, Cu, Co, TiN, Ti, Ta, TaN, Ru, RuN and Al.

The one or more capacitor stacks 200 are located on the second electrode layer 120 in the first capacitor region 100a. Each of the capacitor stacks 200 includes the second capacitor dielectric layer 125 and the third electrode layer 130 located on the second capacitor dielectric layer 125. There exist the projection overlay regions D between the third electrode layer 130 and the second electrode layer 120 and between the adjacent third electrode layers 130. Thereby, in the first capacitor region 100a, capacitors can be formed between the two adjacent electrode layers (between the first electrode layer 110 and the second electrode layer 120, between the second electrode layer 120 and the third electrode layer 130, and between the adjacent third electrode layers 130), which is beneficial to improving the capacitance density of the first capacitor region 100a.

Moreover, in this implementation, the one or more second capacitor dielectric layers 125 are further located on the first capacitor dielectric layer 115 in the second capacitor region 100b. The third electrode layer 130 in the capacitor stack 200 at the top is used as the top electrode layer 130a. The top electrode layer 130a is further located on the one or more second capacitor dielectric layers 125 in the second capacitor region 100b, and there exists the projection overlay region E between the top electrode layer and the first electrode layer 110. Therefore, in the second capacitor region 100b, a capacitor is formed between the first electrode layer 110 and the top electrode layer 130a, and the first capacitor dielectric layer 115 and the one or more second capacitor dielectric layers 125 are arranged between the first electrode layer 110 and the top electrode layer 130a, which increases the thickness of the capacitor dielectric layer between the first electrode layer 110 and the top electrode layer 130a, thereby improving the voltage resistance of the capacitor in the second capacitor region 100b.

Thereby, in this implementation, not only the capacitors with good voltage resistance, but also the capacitors with high capacitance density can be formed, thereby meeting the requirements of providing capacitors with different types and performance parameters on the substrate.

In this implementation, for convenience of illustration and explanation, the description will be made in an example where the number of the capacitor stacks 200 is one.

In other implementations, the number of the capacitor stacks may also be plural. The more the capacitor stacks, the higher the capacitance density of the first capacitor region; and the more the second capacitor dielectric layers in the second capacitor region, the larger the thickness of the capacitor dielectric layer between the first electrode layer and the top electrode layer in the second capacitor region, and the higher the voltage resistance of the capacitor in the second capacitor region.

In each capacitor stack 200, the second capacitor dielectric layer 125 is used for forming the insulating layer in the MIM capacitor. Specifically, the second capacitor dielectric layer 125 located in the first capacitor region 100a is used for isolating the second electrode layer 120 and the third electrode layer 130 and isolating the adjacent third electrode layers. The second capacitor dielectric layer 125 located in the second capacitor region 100b is used for isolating the first electrode layer 110 and the top electrode layer 130a together with the first capacitor dielectric layer 115.

A material of the second capacitor dielectric layer 125 is an insulating dielectric material. In this implementation, the material of the second capacitor dielectric layer 125 is a high k dielectric material. The high k dielectric material is a dielectric material with a relative dielectric constant greater than a relative dielectric constant of the silicon oxide. The use of the high k dielectric material is beneficial to increasing the capacitance value of the MIM capacitor and the capacitance density accordingly.

In an example, the material of the second capacitor dielectric layer 125 includes one or more of HfO₂, HfSiO, TiO₂, HfZrO, HfSiON, HfTaO, HfTiO, Ta₂O₅, ZrO₂, ZrSiO₂, Al₂O₃, SrTiO₃, BaSrTiO and SiN.

In this implementation, the materials of the second capacitor dielectric layer 125 and the first capacitor dielectric layer 115 are the same. In other implementations, the materials of the second capacitor dielectric layer and the first capacitor dielectric layer may be different.

In this implementation, the description is made in an example where the number of the capacitor stacks 200 is one, and correspondingly, the number of the second capacitor dielectric layers 125 is also one. In other implementations, when the number of the capacitor stacks is another number, the number of the second capacitor dielectric layers is correspondingly another number.

The third electrode layer 130 is used as a plate electrode of the MIM capacitor.

In this implementation, there exist projection overlay regions D between the third electrode layer 130 and the second electrode layer 120 and between the adjacent third electrode layers 130, so that capacitors can be formed between the third electrode layer 130 and the second electrode layer 120 and between the adjacent third electrode layers 130.

In this implementation, “there exist projection overlay regions D between the third electrode layer 130 and the second electrode layer 120 and between the adjacent third electrode layers 130” means that in the projective plane parallel with the surface of the substrate 100, there exist overlay regions between the third electrode layer 130 and the second electrode layer 120 and between the adjacent third electrode layers 130.

In this implementation, there exists a projection overlay region E between the top electrode layer 130a and the first electrode layer 110, so that a capacitor can be formed between the top electrode layer 130a and the first electrode layer 110.

In this implementation, “there exists a projection overlay region E between the top electrode layer 130a and the first electrode layer 110” means that in the projective plane parallel with the surface of the substrate 100, there exists an overlay region E between the top electrode layer 130a and the first electrode layer 110.

A material of the third electrode layer 130 is a conductive material. In an example, the material of the third electrode layer 130 includes one or more of W, Cu, Co, TiN, Ti, Ta, TaN, Ru, RuN and Al.

Along a direction of a surface normal of the substrate 100, a direction in which the first electrode layer 110 points to the second electrode layer 120 is a vertical direction, and along the vertical direction, the third electrode layers 130 in the one or more capacitor stacks 200 include: odd-numbered third electrode layers 130 and even-numbered third electrode layers 130.

In this implementation, the odd-numbered third electrode layers 130 expose the second connection region II and are further located in the first connection region I, so that the even-numbered third electrode layers 130 can cover the second connection region II, so that the second conductive plug, which is electrically connected to the second electrode layer 120 or to the second electrode layer 120 and the even-numbered third electrode layers 130, can be arranged in the second connection region II.

In this implementation, when the number of the capacitor stacks 200 is plural, the even-numbered third electrode layers 130 cover the second connection region II and further expose the first connection region I, so that all the odd-numbered third electrode layers 130 can be located in the first connection region I, and thereby, the first conductive plug, which is electrically connected to the first electrode layer 110 and the odd-numbered third electrode layers 130, can be arranged in the first connection region I.

In this implementation, the top electrode layer 130a exposes the third connection region III, so that the first electrode layer 110 located in the third connection region III can be exposed, and thereby, the third conductive plug electrically connected to the first electrode layer 110 can be arranged in the third connection region II.

In this implementation, the top electrode layer 130a is further located on the substrate 100 on a side of the first electrode layer 110, and the part of the top electrode layer 130a located on the substrate 100 on the side of the first electrode layer 110 is used as a fourth connection region IV, so that the fourth conductive plug electrically connected to the top electrode layer 130 can be arranged in the fourth connection region IV.

In this implementation, the metal-insulator-metal capacitor structure further includes: a first conductive plug 210, located in the first capacitor region 100a and electrically connected to the first electrode layer 110 and the odd-numbered third electrode layers 130; and a second conductive plug 220, located in the first capacitor region 100a and electrically connected to the second electrode layer 120, or electrically connected to the second electrode layer 120 and the even-numbered third electrode layers 130.

The first conductive plug 210 is used to be electrically connected to the first electrode layer 110 and the odd-numbered third electrode layers 130 and to an external circuit, so that the first electrode layer 110 and the odd-numbered third electrode layers 130 can be connected to the same potential.

In this implementation, in the first capacitor region 100a, the first conductive plug 210 is located in the first connection region I, the first conductive plug 210 runs through the odd-numbered third electrode layers 130 and contacts the first electrode layer 110, and a side wall of the first conductive plug 210 contacts the odd-numbered third electrode layers 130, so that the first conductive plug 210 can be electrically connected to the first electrode layer 110 and the odd-numbered third electrode layers 130.

In this implementation, in the first capacitor region 100a, the first conductive plug 210 further runs through the first electrode layer 110 and contacts the top metal layer 105 in the first connection region I, so that the top metal layer 105 can be electrically connected to the first electrode layer 110 and the odd-numbered third electrode layers 130.

In this implementation, in the first capacitor region 100a, the first conductive plug 210 further runs through the top dielectric layer 103 and the etch stop layer 102 on the top of the top metal layer 105 in the first connection region I. The etch stop layer 102 can function to define the etch stop position during the formation of the first conductive plug 210, thereby reducing the probability of damage to the top metal layer 105 by the process of forming the first conductive plug 210, and improving the consistency of depths of the bottoms of the first conductive plug 210.

The second conductive plug 220 is used to be electrically connected to the second electrode layer 120 and the external circuit, or when the number of the capacitor stacks 200 is plural, the second conductive plug 220 is used to be electrically connected to the second electrode layer 120 and the even-numbered third electrode layers 130 and to the external circuit, so that the second electrode layer 120 and the even-numbered third electrode layers 130 can be connected to the same potential.

Accordingly, the first electrode layer 110 and the second electrode layer 120 are connected to different potentials, the second electrode layer 120 and the third electrode layer 130 adjacent to the second electrode layer 120 are connected to different potentials, and when the number of the third electrode layers 130 is plural, the two adjacent third electrode layers 130 are also connected to different potentials, so that in the first capacitor region 100a, capacitors can be formed between the first electrode layer 110 and the second electrode layer 120, between the second electrode layer 120 and the third electrode layer 130 adjacent to the second electrode layer 120, and between the two adjacent third electrode layers 130.

In this implementation, in the first capacitor region 100a, the second conductive plug 220 is located in the second connection region 100b, and the second conductive plug 220 contacts the second electrode layer 120, so that the second conductive plug 220 can be electrically connected to the second electrode layer 120; or the second conductive plug 220 runs through the even-numbered third electrode layers 130 and contacts the second electrode layer 120 and a side wall of the second conductive plug 220 contacts the even-numbered third electrode layers 130, so that the second conductive plug 220 can be electrically connected to the second electrode layer 120 and the even-numbered third electrode layers 130.

In this implementation, in the first capacitor region 100a, the second conductive plug 220 further runs through the second electrode layer 120 and contacts the top metal layer 105 in the second connection region II, so that the second conductive plug 220 can be electrically connected to the second electrode layer 120 and the top metal layer 105.

More specifically, in this implementation, the second conductive plug 220 runs through the etch stop layer 102 and the top dielectric layer 103 on the top of the top metal layer 105 in the second connection region II. The etch stop layer 102 can define the etch stop position during the formation of the second conductive plug 220, which can reduce the probability of damage to the top metal layer 105 during the formation of the second conductive plug 220 and improve the consistency of depths of the bottoms of the second conductive plugs 220.

A material of the first conductive plug 210 and the second conductive plug 220 is a conductive material. In this implementation, the material of the first conductive plug 210 and the second conductive plug 220 includes one or more of W, Cu, Co, TiN, Ti, Ta, TaN, Ru, RuN and Al.

In this implementation, the metal-insulator-metal capacitor structure further includes: a third conductive plug 230, located in the second capacitor region 100b and electrically connected to the first electrode layer 110; and a fourth conductive plug 240, located in the second capacitor region 100b and electrically connected to the top electrode layer 130a.

The third conductive plug 230 is used to be electrically connected to the first electrode layer 110 of the second capacitor region 100b and the external circuit.

In this implementation, in the second capacitor region 100b, the third conductive plug 230 is located in the third connection region III and contacts the first electrode layer 110, so that the third conductive plug 230 can be electrically connected to the first electrode layer 110.

In this implementation, in the second capacitor region 100b, the third conductive plug 230 further runs through the first electrode layer 110 and contacts the top metal layer 105 in the third connection region III, so that the third conductive plug 230 can be electrically connected to the top metal layer 105 in the third connection region III.

More specifically, in this implementation, in the second capacitor region 100b, the third conductive plug 230 runs through the etch stop layer 102 and the top dielectric layer 103 on the top of the top metal layer 105 in the third connection region III. The etch stop layer 102 can define the etch stop position during the formation of the third conductive plug 230, thereby reducing the probability of damage to the top metal layer 105 by the process of forming the third conductive plug 230 and improving the consistency of depths of the bottoms of the third conductive plugs 230.

The fourth conductive plug 240 is used to be electrically connected to the top electrode layer 130a in the second capacitor region 100b and the external circuit.

In this implementation, the fourth conductive plug 240 and the third conductive plug 230 are connected to different potentials, so that the first electrode layer 110 and the top electrode layer 130a in the second capacitor region 100b are connected to different potentials.

In this implementation, in the second capacitor region 100b, the fourth conductive plug 240 is located in the fourth connection region IV and contacts the top electrode layer 130a, so that the fourth conductive plug 240 can be electrically connected to the top electrode layer 130a.

In this implementation, in the second capacitor region 100b, the fourth conductive plug 240 further runs through the top electrode layer 130a and contacts the top metal layer 105 in the fourth connection region IV, so that the fourth conductive plug 240 can be electrically connected to the top electrode layer 130a in the second capacitor region 100b and the top metal layer 105 in the fourth connection region IV.

More specifically, in this implementation, in the second capacitor region 100b, the fourth conductive plug 240 further runs through the etch stop layer 102 and the top dielectric layer 103 on the top of the top metal layer 105 in the fourth connection region IV. The etch stop layer 102 can define the etch stop position during the formation of the fourth conductive plug 240, thereby reducing the probability of damage to the top metal layer 105 by the process of forming the fourth conductive plug 240 and improving the consistency of depths of the bottoms of the fourth conductive plugs 240.

A material of the third conductive plug 230 and the fourth conductive plug 240 is a conductive material. In this implementation, the material of the third conductive plug 230 and the fourth conductive plug 240 includes one or more of W, Cu, Co, TiN, Ti, Ta, TaN, Ru, RuN and Al.

In this implementation, the metal-insulator-metal capacitor structure further includes: a cover dielectric layer 250, located on the substrate 100 and covering the capacitor stack 200, and the second capacitor dielectric layer 125 and the top electrode layer 130a in the second capacitor region 100b.

The cover dielectric layer 250 is used for covering the capacitor stack 200, and the second capacitor dielectric layer 125 and the top electrode layer 130a in the second capacitor region 100b, and also for providing a process basis for the formation of the first conductive plug 210, the second conductive plug 220, the third conductive plug 230 and the fourth conductive plug 240 and realizing electrical isolation between the first conductive plug 210, the second conductive plug 220, the third conductive plug 230 and the fourth conductive plug 240.

Accordingly, in this implementation, the first conductive plug 210, the second conductive plug 220, the third conductive plug 230 and the fourth conductive plug 240 are located in the cover dielectric layer 250.

A material of the cover dielectric layer 250 is a dielectric material. In an example, the material of the cover dielectric layer 250 is silicon oxide.

The metal-insulator-metal capacitor structure may be formed by a method for forming a metal-insulator-metal capacitor structure provided by an implementation of the present disclosure, and may also be formed by other methods.

Accordingly, the present disclosure further provides a method for forming a metal-insulator-metal capacitor structure. FIG. 2 to FIG. 7 are schematic structural views corresponding to steps of a method for forming a metal-insulator-metal capacitor structure according to an implementation of the present disclosure.

The method for forming a metal-insulator-metal capacitor structure in this implementation will be described in detail below in conjunction with the accompanying drawings.

Referring to FIG. 2, a substrate including a first capacitor region 100a and a second capacitor region 100b is provided.

The substrate 100 is used for providing a process platform for forming an MIM capacitor.

In this implementation, the substrate 100 includes a device structure layer (not shown) and a back-end-of-line interconnect layer (not shown) located on the device structure layer and electrically connected to the device structure layer. The back-end-of-line interconnect layer includes a bottom dielectric layer 101 and one or more metal layers located in the bottom dielectric layer 101, and the plurality of metal layers located at a top are used as top metal layers 105.

The device structure layer is formed by a front-end-of-line device manufacturing process. In specific implementation, the device structure layer may include a substrate and device structures located on the substrate. The device structures may include MOS transistors and the like, such as NMOS transistors and PMOS transistors.

In an example, the substrate is a silicon substrate. In other implementations, a material of the substrate may also be germanium, silicon germanide, silicon carbide, gallium arsenide, indium gallide or the like, and the substrate may also be a silicon-on-insulator substrate, a germanium-on-insulator substrate or other types of substrates.

The back-end-of-line interconnect layer is formed by a back-end-of-line interconnect process.

In this implementation, the back-end-of-line interconnect layer includes the bottom dielectric layer 101 and the one or more metal layers located in the bottom dielectric layer 101, and the plurality of metal layers located at the top are used as the top metal layers 105.

The bottom dielectric layer 101 is used for isolating the metal layers. Specifically, the bottom dielectric layer 101 is an inter metal dielectric (IMD) layer.

A material of the bottom dielectric layer 101 is a dielectric material. In an example, the material of the bottom dielectric layer 101 is silicon oxide.

In this implementation, the adjacent metal layers are electrically connected to each other so as to electrically lead out the device structures in the device structure layer through the one or more metal layers. Specifically, the two adjacent metal layers are electrically connected through a via interconnect structure located therebetween. The device structures in the device structure layer are electrically led out through the top metal layers 105.

A material of the metal layers is a conductive material. In this implementation, the material of the metal layers includes one or more of W, Cu, Co, TiN, Ti, Ta, TaN, Ru, RuN and Al.

The first capacitor region 100a and the second capacitor region 100b are respectively used for forming capacitors. Specifically, in this implementation, capacitors with different types and performance parameters are respectively formed in the first capacitor region 100a and the second capacitor region 100b.

In this implementation, the substrate 100 further includes: an etch stop layer 102, located on the bottom dielectric layer 101 and covering the top metal layer 105; and a top dielectric layer 103, located on the etch stop layer 102.

The etch stop layer 102 is used for defining an etch stop position in the steps of forming the first conductive plug, the second conductive plug, the third conductive plug and the fourth conductive plug, which reduces the damage to the top metal layer 105 and is beneficial to improving the consistency of heights of bottoms of the first conductive plug, the second conductive plug, the third conductive plug and the fourth conductive plug.

In an example, a material of the etch stop layer 102 is silicon nitride. In other implementations, the material of the etch stop layer may also be other materials that have high etch selectivity with the substrate material, for example, one or more of silicon nitride, aluminum oxide, aluminum nitride and NDC (nitride doped carbon).

The top dielectric layer 103 is used for isolating the top metal layer 105 and the first electrode layer 110.

A material of the top dielectric layer 103 is a dielectric material. In an example, the material of the top dielectric layer 103 is silicon oxide.

Referring to FIG. 3, a plurality of first electrode layers 110, which are respectively located in the first capacitor region 100a and the second capacitor region 100b, are formed on the substrate 100.

The first electrode layer 110 is used as a plate electrode of the MIM capacitor.

A material of the first electrode layer 110 is a conductive material. In an example, the material of the first electrode layer 110 includes one or more of W, Cu, Co, TiN, Ti, Ta, TaN, Ru, RuN and Al.

In this implementation, the step of forming the first electrode layer 110 includes: the substrate 100 is covered with a first electrode material layer (not shown); and the first electrode material layer is patterned while a part of the first electrode material layer located in the first capacitor region 100a and the second capacitor region 100b is reserved as the first electrode layer 110.

In this implementation, the process of forming the first electrode material layer includes any one of a physical vapor deposition process and a chemical vapor deposition process.

In this implementation, an anisotropic dry etching process is used to pattern the first electrode material layer.

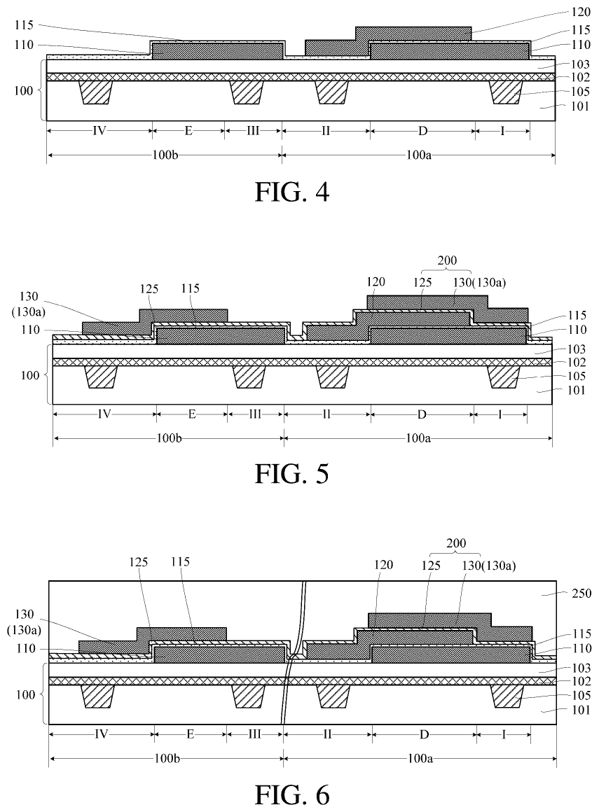

Referring to FIG. 4, a first capacitor dielectric layer 115 is formed on the first electrode layer 110.

The first capacitor dielectric layer 115 is used as an insulating layer in the MIM capacitor. The first capacitor dielectric layer 115 located in the first capacitor region 100a is used for isolating the first electrode layer 110 and the subsequent second electrode layer. The first capacitor dielectric layer 115 located in the second capacitor region 100b is used for isolating the first electrode layer 110 and the top electrode layer together with the subsequent second capacitor dielectric layer.

Specifically, the first capacitor dielectric layer 115 conformally covers the first electrode layer 110 and the substrate 100.

A material of the first capacitor dielectric layer 115 is an insulating dielectric material.

In this implementation, the material of the first capacitor dielectric layer 115 is a high k dielectric material. The high k dielectric material is a dielectric material with a relative dielectric constant greater than a relative dielectric constant of the silicon oxide. The use of the high k dielectric material is beneficial to increasing the capacitance value of the MIM capacitor and the capacitance density accordingly.

In an example, the material of the first capacitor dielectric layer 115 includes one or more of HfO₂, HfSiO, TiO₂, HfZrO, HfSiON, HfTaO, HfTiO, Ta₂O₅, ZrO₂, ZrSiO₂, Al₂O₃, SrTiO₃, BaSrTiO and SiN.

In this implementation, the process of forming the first capacitor dielectric layer 115 includes a chemical vapor deposition process or an atomic layer deposition process.

Still referring to FIG. 4, a second electrode layer 120 is formed on the first capacitor dielectric layer 115 in the first capacitor region 100a.

The second electrode layer 120 is used as a plate electrode of the MIM capacitor.

In this implementation, the second electrode layer 120 exposes a part of a top of the first electrode layer 110. In the first capacitor region 100a, the part of the top of the first electrode layer 110 exposed by the second electrode layer 120 is used as a first connection region I.

In this implementation, in the first capacitor region 100a, the first connection region I is used for forming the first conductive plug, so that the first conductive plug is electrically connected to the first electrode layer 110 or the first conductive plug is electrically connected to the first electrode layer 110 and the odd-numbered third electrode layers 130.

In this implementation, in the first capacitor region 100a, the second electrode layer 120 is further located on the substrate 100 on a side of the first electrode layer 110, and the part of the second electrode layer 120 located on the substrate 100 on the side of the first electrode layer 110 is used as a second connection region II.

In this implementation, in the first capacitor region 100a, the second connection region II is used for forming the second conductive plug, so that the second conductive plug is electrically connected to the second electrode layer, or to the second electrode layer and the even-numbered third electrode layers.

A material of the second electrode layer 120 is a conductive material. In an example, the material of the second electrode layer 120 includes one or more of W, Cu, Co, TiN, Ti, Ta, TaN, Ru, RuN and Al.

In this implementation, the step of forming the second electrode layer 120 includes: the first capacitor dielectric layer 115 is covered with a second electrode material layer (not shown); and the second electrode material layer is patterned while a part of the second electrode material layer located in the first capacitor region 100a is reserved as the second electrode layer 120.

In this implementation, the process of forming the second electrode material layer includes any one of a physical vapor deposition process and a chemical vapor deposition process.

In this implementation, an anisotropic dry etching process is used to pattern the second electrode material layer.

Referring to FIG. 5, after the second electrode layer 120 is formed, one or more capacitor stacks 200 are formed in the first capacitor region 100a. Each of the capacitor stacks 200 includes a second capacitor dielectric layer 125 and a third electrode layer 130 located on the second capacitor dielectric layer 125. There exist projection overlay regions between the third electrode layer 130 and the second electrode layer 120 and between the adjacent third electrode layers 130.

The one or more capacitor stacks 200 are located on the second electrode layer 120 in the first capacitor region 100a. Each of the capacitor stacks 200 includes the second capacitor dielectric layer 125 and the third electrode layer 130 located on the second capacitor dielectric layer 125. There exist the projection overlay regions D between the third electrode layer 130 and the second electrode layer 120 and between the adjacent third electrode layers 130. Thereby, in the first capacitor region 100a, capacitors can be formed between the two adjacent electrode layers (between the first electrode layer 110 and the second electrode layer 120, between the second electrode layer 120 and the third electrode layer 130, and between the adjacent third electrode layers 130), which is beneficial to improving the capacitance density of the first capacitor region 100a.

Moreover, in this implementation, in the step of forming the second capacitor dielectric layer 125, the one or more second capacitor dielectric layers 125 are further formed on the first capacitor dielectric layer 115 in the second capacitor region 100b. The third electrode layer 130 in the capacitor stack 200 at the top is used as the top electrode layer 130a. The top electrode layer 130a is further formed on the one or more second capacitor dielectric layers 125 in the second capacitor region 100b, and there exists the projection overlay region E between the top electrode layer and the first electrode layer 110. Therefore, in the second capacitor region 100b, a capacitor is formed between the first electrode layer 110 and the top electrode layer 130a, and the first capacitor dielectric layer 115 and the one or more second capacitor dielectric layers 125 are arranged between the first electrode layer 110 and the top electrode layer 130a, which increases the thickness of the capacitor dielectric layer between the first electrode layer 110 and the top electrode layer 130a, thereby improving the voltage resistance of the capacitor in the second capacitor region 100b.

Thereby, in this implementation, not only the capacitors with good voltage resistance, but also the capacitors with high capacitance density can be formed, thereby meeting the requirements of providing capacitors with different types and performance parameters on the substrate 100.

In each capacitor stack 200, the second capacitor dielectric layer 125 is used for forming the insulating layer in the MIM capacitor. Specifically, the second capacitor dielectric layer 125 located in the first capacitor region 100a is used for isolating the second electrode layer 120 and the third electrode layer 130 and isolating the adjacent third electrode layers 130. The second capacitor dielectric layer 125 located in the second capacitor region 100b is used for isolating the first electrode layer 110 and the top electrode layer 130a together with the first capacitor dielectric layer 115.

A material of the second capacitor dielectric layer 125 is an insulating dielectric material.

In this implementation, the material of the second capacitor dielectric layer 125 is a high k dielectric material. The high k dielectric material is a dielectric material with a relative dielectric constant greater than a relative dielectric constant of the silicon oxide. The use of the high k dielectric material is beneficial to increasing the capacitance value of the MIM capacitor and the capacitance density accordingly.

In an example, the material of the second capacitor dielectric layer 125 includes one or more of HfO₂, HfSiO, TiO₂, HfZrO, HfSiON, HfTaO, HfTiO, Ta₂O₅, ZrO₂, ZrSiO₂, Al₂O₃, SrTiO₃, BaSrTiO and SiN.

In this implementation, the materials of the second capacitor dielectric layer 125 and the first capacitor dielectric layer 115 are the same. In other implementations, the materials of the second capacitor dielectric layer and the first capacitor dielectric layer may be different.

In this implementation, the description is made in an example where the number of the capacitor stacks 200 is one, and correspondingly, the number of the second capacitor dielectric layers 125 is also one. In other implementations, when the number of the capacitor stacks is another number, the number of the second capacitor dielectric layers is correspondingly another number.

The third electrode layer 130 is used as a plate electrode of the MIM capacitor.

In this implementation, there exist projection overlay regions D between the third electrode layer 130 and the second electrode layer 120 and between the adjacent third electrode layers 130, so that capacitors can be formed between the third electrode layer 130 and the second electrode layer 120 and between the adjacent third electrode layers 130.

In this implementation, “there exist projection overlay regions D between the third electrode layer 130 and the second electrode layer 120 and between the adjacent third electrode layers 130” means that in the projective plane parallel with the surface of the substrate 100, there exist overlay regions between the third electrode layer 130 and the second electrode layer 120 and between the adjacent third electrode layers 130.

In this implementation, there exists a projection overlay region E between the top electrode layer 130a and the first electrode layer 110, so that a capacitor can be formed between the top electrode layer 130a and the first electrode layer 110.

In this implementation, “there exists a projection overlay region E between the top electrode layer 130a and the first electrode layer 110” means that in the projective plane parallel with the surface of the substrate 100, there exists an overlay region E between the top electrode layer 130a and the first electrode layer 110.

A material of the third electrode layer 130 is a conductive material. In an example, the material of the third electrode layer 130 includes one or more of W, Cu, Co, TiN, Ti, Ta, TaN, Ru, RuN and Al.

In this implementation, along a direction of a surface normal of the substrate 100, a direction in which the first electrode layer 110 points to the second electrode layer 120 is a vertical direction, and along the vertical direction, the third electrode layers 130 in the one or more capacitor stacks 200 include: odd-numbered third electrode layers 130 and even-numbered third electrode layers 130.

In this implementation, the odd-numbered third electrode layers 130 expose the second connection region II and are further located in the first connection region I, so that the even-numbered third electrode layers 130 can cover the second connection region II, so that the second conductive plug, which is electrically connected to the second electrode layer 120 or to the second electrode layer 120 and the even-numbered third electrode layers 130, can be arranged in the second connection region II.

In this implementation, when the number of the capacitor stacks 200 is plural, the even-numbered third electrode layers 130 cover the second connection region II and further expose the first connection region I, so that all the odd-numbered third electrode layers 130 can be located in the first connection region I, and thereby, the first conductive plug, which is electrically connected to the first electrode layer 110 and the odd-numbered third electrode layers 130, can be arranged in the first connection region I.

In this implementation, the top electrode layer 130a exposes the third connection region III, so that the first electrode layer 110 located in the third connection region III can be exposed, and thereby, the third conductive plug electrically connected to the first electrode layer 110 can be arranged in the third connection region II.

In this implementation, the top electrode layer 130a is further located on the substrate 100 on a side of the first electrode layer 110, and the part of the top electrode layer 130a located on the substrate 100 on the side of the first electrode layer 110 is used as a fourth connection region IV, so that the fourth conductive plug electrically connected to the top electrode layer 130 can be arranged in the fourth connection region IV.

In this implementation, the step of forming the capacitor stack 200 includes: the substrate 100 is conformally covered with a second capacitor dielectric layer 125; the second capacitor dielectric layer 125 is covered with a third electrode material layer (not shown); and the third electrode material layer is patterned to remove the third electrode material layer located in the second capacitor region 100b while a part of the third electrode material layer located in the first capacitor region 100a is reserved as the third electrode layer 130.

In this implementation, the process of forming the second capacitor dielectric layer 125 includes a chemical vapor deposition process or an atomic layer deposition process.

In this implementation, the process of forming the third electrode material layer includes any one of a physical vapor deposition process and a chemical vapor deposition process.

In this implementation, an anisotropic dry etching process is used to pattern the third electrode material layer.

Referring to FIG. 6, in this implementation, the method for forming a metal-insulator-metal capacitor structure further includes: after the one or more capacitor stacks 200 are formed, a cover dielectric layer 250 is formed on the substrate 100.

The cover dielectric layer 250 is used for covering the capacitor stack 200, and the second capacitor dielectric layer 125 and the top electrode layer 130a in the second capacitor region 100b, and also for providing a process basis for the formation of the first conductive plug, the second conductive plug, the third conductive plug and the fourth conductive plug and realizing electrical isolation between the first conductive plug, the second conductive plug, the third conductive plug and the fourth conductive plug.

A material of the cover dielectric layer 250 is a dielectric material. In an example, the material of the cover dielectric layer 250 is silicon oxide.

In an example, a chemical vapor deposition process is used to form the cover dielectric layer 250.

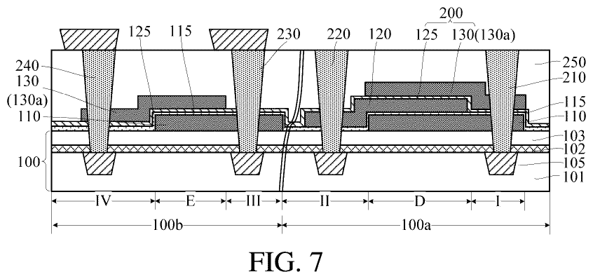

Referring to FIG. 7, the method for forming a metal-insulator-metal capacitor structure further includes: after the one or more capacitor stacks 200 are formed, forming a first conductive plug 210, which is electrically connected to the first electrode layer 110 and the odd-numbered third electrode layers 130, in the first capacitor region 100a; and forming a second conductive plug 220 in the first capacitor region 100a. The second conductive plug 220 is electrically connected to the second electrode layer 120, or the second conductive plug 220 is electrically connected to the second electrode layer 120 and the even-numbered third electrode layers 130.

Specifically, in this implementation, after the cover dielectric layer 250 is formed, the first conductive plug 210 and the second conductive plug 220 are formed. The first conductive plug 210 and the second conductive plug 220 are correspondingly formed in the cover dielectric layer 250.

The first conductive plug 210 is used to be electrically connected to the first electrode layer 110 and the odd-numbered third electrode layers 130 and to an external circuit, so that the first electrode layer 110 and the odd-numbered third electrode layers 130 can be connected to the same potential.

In this implementation, the step of forming the first conductive plug 210 includes: in the first capacitor region 100a, the first conductive plug 210 is formed in the first connection region I. The first conductive plug 210 runs through the odd-numbered third electrode layers 130 and contacts the first electrode layer 110, and a side wall of the first conductive plug 210 contacts the odd-numbered third electrode layers 130, so that the first conductive plug 210 can be electrically connected to the first electrode layer 110 and the odd-numbered third electrode layers 130.

In this implementation, in the step of forming the first conductive plug 210, in the first capacitor region 100a, the first conductive plug 210 further runs through the first electrode layer 110 and contacts the top metal layer 105 in the first connection region I, so that the top metal layer 105 can be electrically connected to the first electrode layer 110 and the odd-numbered third electrode layers 130.

In this implementation, in the first capacitor region 100a, the first conductive plug 210 further runs through the top dielectric layer 103 and the etch stop layer 102 on the top of the top metal layer 105 in the first connection region I. The etch stop layer 102 can function to define the etch stop position during the formation of the first conductive plug 210, thereby reducing the probability of damage to the top metal layer 105 by the process of forming the first conductive plug 210, and improving the consistency of depths of the bottoms of the first conductive plug 210.

The second conductive plug 220 is used to be electrically connected to the second electrode layer 120 and the external circuit, or when the number of the capacitor stacks 200 is plural, the second conductive plug 220 is used to be electrically connected to the second electrode layer 120 and the even-numbered third electrode layers 130 and to the external circuit, so that the second electrode layer 120 and the even-numbered third electrode layers 130 can be connected to the same potential.

Accordingly, the first electrode layer 110 and the second electrode layer 120 are connected to different potentials, the second electrode layer 120 and the third electrode layer 130 adjacent to the second electrode layer 120 are connected to different potentials, and when the number of the third electrode layers 130 is plural, the two adjacent third electrode layers 130 are also connected to different potentials, so that in the first capacitor region 100a, capacitors can be formed between the first electrode layer 110 and the second electrode layer 120, between the second electrode layer 120 and the third electrode layer 130 adjacent to the second electrode layer 120, and between the two adjacent third electrode layers 130.

In this implementation, the step of forming the second conductive plug 220 includes: in the first capacitor region 100a, the second conductive plug 220 is formed in the second connection region 100b. The second conductive plug 220 contacts the second electrode layer 120, so that the second conductive plug 220 can be electrically connected to the second electrode layer 120; or the second conductive plug 220 runs through the even-numbered third electrode layers 130 and contacts the second electrode layer 120 and a side wall of the second conductive plug 220 contacts the even-numbered third electrode layers 130, so that the second conductive plug 220 can be electrically connected to the second electrode layer 120 and the even-numbered third electrode layers 130.

In this implementation, in the step of forming the second conductive plug 220, in the first capacitor region 100a, the second conductive plug 220 further runs through the second electrode layer 120 and contacts the top metal layer 105 in the second connection region II, so that the second conductive plug 220 can be electrically connected to the second electrode layer 120 and the top metal layer 105.

More specifically, in this implementation, the second conductive plug 220 runs through the etch stop layer 102 and the top dielectric layer 103 on the top of the top metal layer 105 in the second connection region II. The etch stop layer 102 can define the etch stop position during the formation of the second conductive plug 220, which can reduce the probability of damage to the top metal layer 105 during the formation of the second conductive plug 220 and improve the consistency of depths of the bottoms of the second conductive plugs 220.

A material of the first conductive plug 210 and the second conductive plug 220 is a conductive material. In this implementation, the material of the first conductive plug 210 and the second conductive plug 220 includes one or more of W, Cu, Co, TiN, Ti, Ta, TaN, Ru, RuN and Al.

Referring to FIG. 7, the method for forming a metal-insulator-metal capacitor structure further includes: after the one or more capacitor stacks 200 are formed, a third conductive plug 230, which is electrically connected to the first electrode layer 110, is formed in the second capacitor region 100b; and a fourth conductive plug 240, which is electrically connected to the top electrode layer 130a, is formed in the second capacitor region 100b.

In this implementation, the first conductive plug 210, the second conductive plug 220, the third conductive plug 230 and the fourth conductive plug 240 are located in the cover dielectric layer 250.

The third conductive plug 230 is used to be electrically connected to the first electrode layer 110 of the second capacitor region 100b and the external circuit.

In this implementation, the step of forming the third conductive plug 230 includes: in the second capacitor region 100b, the third conductive plug 230 contacting the first electrode layer 110 is formed in the third connection region III, so that the third conductive plug 230 can be electrically connected to the first electrode layer 110.

In this implementation, in the step of forming the third conductive plug 230, in the second capacitor region 100b, the third conductive plug 230 further runs through the first electrode layer 110 and contacts the top metal layer 105 in the third connection region III, so that the third conductive plug 230 can be electrically connected to the top metal layer 105 in the third connection region III.

More specifically, in this implementation, in the second capacitor region 100b, the third conductive plug 230 runs through the etch stop layer 102 and the top dielectric layer 103 on the top of the top metal layer 105 in the third connection region III. The etch stop layer 102 can define the etch stop position during the formation of the third conductive plug 230, thereby reducing the probability of damage to the top metal layer 105 by the process of forming the third conductive plug 230 and improving the consistency of depths of the bottoms of the third conductive plugs 230.

The fourth conductive plug 240 is used to be electrically connected to the top electrode layer 130a in the second capacitor region 100b and the external circuit.

In this implementation, the fourth conductive plug 240 and the third conductive plug 230 are connected to different potentials, so that the first electrode layer 110 and the top electrode layer 130a in the second capacitor region 100b are connected to different potentials.

In this implementation, the step of forming the fourth conductive plug 240 includes: in the second capacitor region 100b, the fourth conductive plug 240 contacting the top electrode layer 130a is formed in the fourth connection region IV, so that the fourth conductive plug 240 can be electrically connected to the top electrode layer 130a.

In this implementation, in the step of forming the fourth conductive plug 240, in the second capacitor region 100b, the fourth conductive plug 240 further runs through the top electrode layer 130a and contacts the top metal layer 105 in the fourth connection region IV, so that the fourth conductive plug 240 can be electrically connected to the top electrode layer 130a in the second capacitor region 100b and the top metal layer 105 in the fourth connection region IV.

More specifically, in this implementation, in the second capacitor region 100b, the fourth conductive plug 240 further runs through the etch stop layer 102 and the top dielectric layer 103 on the top of the top metal layer 105 in the fourth connection region IV. The etch stop layer 102 can define the etch stop position during the formation of the fourth conductive plug 240, thereby reducing the probability of damage to the top metal layer 105 by the process of forming the fourth conductive plug 240 and improving the consistency of depths of the bottoms of the fourth conductive plugs 240.

A material of the third conductive plug 230 and the fourth conductive plug 240 is a conductive material. In this implementation, the material of the third conductive plug 230 and the fourth conductive plug 240 includes one or more of W, Cu, Co, TiN, Ti, Ta, TaN, Ru, RuN and Al.

Specifically, In an example, the first conductive plug 210, the second conductive plug 220, the third conductive plug 230 and the fourth conductive plug 240 are formed in one step, which is beneficial to simplifying the process and improving the manufacturing efficiency of the process.

In an example, the step of forming the first conductive plug 210, the second conductive plug 220, the third conductive plug 230 and the fourth conductive plug 240 includes:

A first contact hole (not shown), a second contact hole (not shown), a third contact hole (not shown) and a fourth contact hole (not shown) are correspondingly formed in the first connection region I, the second connection region II, the third connection region III and the fourth connection region IV respectively. The first contact hole runs through the etch stop layer 102, the top dielectric layer 103, the first electrode layer 110 and the capacitor stack 200 which are located on the top of the top metal layer 105 in the first connection region I, and the cover dielectric layer 250. The second contact hole runs through the etch stop layer 102, the top dielectric layer 103 and second electrode layer 120 which are located on the top of the top metal layer 105 in the second connection region II, or the second contact hole runs through the etch stop layer 102, the top dielectric layer 103, the second electrode layer 120 and the capacitor stack 200 which are located on the top of the top metal layer 105 in the second connection region II, and the cover dielectric layer 250. The third contact hole runs through the etch stop layer 102, the top dielectric layer 103, the first electrode layer 110, the first capacitor dielectric layer 115, the second capacitor dielectric layer 125 the cover dielectric layer 250 which are located on the top metal layer 105 in the third connection region III. The fourth contact hole runs through the etch stop layer 102, the top dielectric layer 103, the first capacitor dielectric layer 115, the second capacitor dielectric layer 125 the top dielectric layer 130a which are located on the top metal layer 105 in the fourth connection region IV, and the cover dielectric layer 250.

The first contact hole, the second contact hole, the third contact hole and the fourth contact hole are filled with a conductive material to correspondingly form the first conductive plug 210, the second conductive plug 220, the third conductive plug 230 and the fourth conductive plug 240 respectively.

In this implementation, in the step of forming the first contact hole, the second contact hole, the third contact hole and the fourth contact hole, the etch stop layer 102 can be used for temporarily defining the etch stop position, thereby reducing the probability of damage to the top metal layer 105 by the process of forming the first contact hole, the second contact hole, the third contact hole and the fourth contact hole, and improving the consistency of depths of the bottoms of the first contact hole, the second contact hole, the third contact hole and the fourth contact hole.

In this implementation, an anisotropic dry etching process is used to form the first contact hole, the second contact hole, the third contact hole and the fourth contact hole, so as to improve the profile control ability over the first contact hole, the second contact hole, the third contact hole and the fourth contact hole.

In specific implementation, the step of filling the first contact hole, the second contact hole, the third contact hole and the fourth contact hole with the conductive material to correspondingly form the first conductive plug 210, the second conductive plug 220, the third conductive plug 230 and the fourth conductive plug 240 respectively includes: the first contact hole, the second contact hole, the third contact hole and the fourth contact hole are respectively filled with a conductive material layer, and the conductive material layer further covers the cover dielectric layer 250; and the conductive material layer located on the cover dielectric layer 250 is removed such that the conductive material layers located in the first contact hole, the second contact hole, the third contact hole and the fourth contact hole are respectively used as the first conductive plug 210, the second conductive plug 220, the third conductive plug 230 and the fourth conductive plug 240.

In this implementation, the process of filling the first contact hole, the second contact hole, the third contact hole and the fourth contact hole with the conductive material layer includes one or more of a chemical vapor deposition process, a physical vapor deposition process and an electrochemical plating process.

In this implementation, the removing the conductive material layer located on the cover dielectric layer 250 may include a chemical mechanical polishing process.

Although the present disclosure has been described above, the present disclosure is not limited thereto. Any person skilled in the art can make various changes and modifications without departing from the spirit and scope of the present disclosure, so the scope of protection of the present disclosure shall be subject to the scope defined by the claims.

What is claimed is:

1. A metal-insulator-metal capacitor structure, comprising:
a substrate, comprising a first capacitor region and a second capacitor region;
a plurality of first electrode layers, respectively located on the substrate in the first capacitor region and the second capacitor region;
a first capacitor dielectric layer, located on a first electrode layer of the plurality of first electrode layers;
a second electrode layer, located on the first capacitor dielectric layer in the first capacitor region; and
one or more capacitor stacks, located on the second electrode layer in the first capacitor region, wherein each of the capacitor stacks comprises a second capacitor dielectric layer and a third electrode layer located on the second capacitor dielectric layer, and projection overlay regions exist between the third electrode layer and the second electrode layer and between adjacent third electrode layers;
wherein the one or more second capacitor dielectric layers are further located on the first capacitor dielectric layer in the second capacitor region; and the third electrode layer at a top of the capacitor stack is used as a top electrode layer, the top electrode layer is further located on the one or more second capacitor dielectric layers in the second capacitor region, and a projection overlay region exists between the top electrode layer and the first electrode layer.

2. The metal-insulator-metal capacitor structure according to claim 1, wherein a number of the capacitor stacks is one.

3. The metal-insulator-metal capacitor structure according to claim 1, wherein:
along a direction of a surface normal of the substrate, a direction in which the first electrode layer points to the second electrode layer is a vertical direction, and along the vertical direction, the third electrode layers in the one or more capacitor stacks comprise: odd-numbered third electrode layers and even-numbered third electrode layers; and
the metal-insulator-metal capacitor structure further comprises: a first conductive plug, located in the first capacitor region and electrically connected to the first electrode layer and the odd-numbered third electrode layers; and
a second conductive plug, located in the first capacitor region and electrically connected to the second electrode layer, or electrically connected to the second electrode layer and the even-numbered third electrode layers.

4. The metal-insulator-metal capacitor structure according to claim 3, wherein:
the second electrode layer exposes a part of a top of the first electrode layer, where the part of the top of the first electrode layer exposed by the second electrode layer is used as a first connection region;
the second electrode layer is further located on the substrate on a side of the first electrode layer, and the part of the second electrode layer located on the substrate on the side of the first electrode layer is used as a second connection region;
the odd-numbered third electrode layers expose the second connection region and are further located in the first connection region;
the even-numbered third electrode layers cover the second connection region and further expose the first connection region;
in the first capacitor region, the first conductive plug is located in the first connection region, the first conductive plug runs through the odd-numbered third electrode layers and contacts the first electrode layer, and a side wall of the first conductive plug contacts the odd-numbered third electrode layers; and
in the first capacitor region, the second conductive plug is located in the second connection region and contacts the second electrode layer, or the second conductive plug runs through the even-numbered third electrode layers and contacts the second electrode layer, and a side wall of the second conductive plug contacts the even-numbered third electrode layers.

5. The metal-insulator-metal capacitor structure according to claim 4, wherein:
the substrate comprises a device structure layer and a back-end-of-line interconnect layer located on the device structure layer and electrically connected to the device structure layer, the back-end-of-line interconnect layer comprises a bottom dielectric layer and one or more metal layers located in the bottom dielectric layer, and the metal layers located at top are used as top metal layers;
in the first capacitor region, the first conductive plug further runs through the first electrode layer and contacts the top metal layers in the first connection region; and
in the first capacitor region, the second conductive plug further runs through the second electrode layer and contacts the top metal layers in the second connection region.

6. The metal-insulator-metal capacitor structure according to claim 1, further comprising:
a third conductive plug, located in the second capacitor region and electrically connected to the first electrode layer; and
a fourth conductive plug, located in the second capacitor region and electrically connected to the top electrode layer.

7. The metal-insulator-metal capacitor structure according to claim 6, wherein:
in the second capacitor region, the top electrode layer exposes a part of a top of the first electrode layer, and the part of the top of the first electrode layer exposed by the top electrode layer is used as a third connection region;
the top electrode layer is further located on the substrate on a side of the first electrode layer, and the part of the top electrode layer located on the substrate on the side of the first electrode layer is used as a fourth connection region;
in the second capacitor region, the third conductive plug is located in the third connection region and contacts the first electrode layer; and
in the second capacitor region, the fourth conductive plug is located in the fourth connection region and contacts the top electrode layer.

8. The metal-insulator-metal capacitor structure according to claim 7, wherein:
the substrate comprises a device structure layer and a back-end-of-line interconnect layer located on the device structure layer and electrically connected to the device structure layer, the back-end-of-line interconnect layer comprises a bottom dielectric layer and one or more metal layers located in the bottom dielectric layer, and the metal layers located at a top are used as top metal layers;
in the second capacitor region, the third conductive plug further runs through the first electrode layer and contacts the top metal layers in the third connection region; and
in the second capacitor region, the fourth conductive plug further runs through the top electrode layer and contacts the top metal layers in the fourth connection region.

9. The metal-insulator-metal capacitor structure according to claim 1, wherein:
a material of the first capacitor dielectric layer comprises hafnium oxide, aluminum oxide or zirconium oxide; and
a material of the second capacitor dielectric layer comprises hafnium oxide, aluminum oxide or zirconium oxide.

10. The metal-insulator-metal capacitor structure according to claim 1, wherein materials of the second capacitor dielectric layer and materials of the first capacitor dielectric layer are same.

11. The metal-insulator-metal capacitor structure according to claim 1, wherein:
a material of the first electrode layer comprises at least one of W, Cu, Co, TiN, Ti, Ta, TaN, Ru, RuN or Al;
a material of the second electrode layer comprises at least one of W, Cu, Co, TiN, Ti, Ta, TaN, Ru, RuN or Al; and
a material of the third electrode layer comprises at least one of W, Cu, Co, TiN, Ti, Ta, TaN, Ru, RuN or Al.

12. A method for forming a metal-insulator-metal capacitor structure, comprising:
providing a substrate comprising a first capacitor region and a second capacitor region;
forming a plurality of first electrode layers, which are respectively located in the first capacitor region and the second capacitor region, on the substrate;
forming a first capacitor dielectric layer on a first electrode layer of the plurality of first electrode layers;
forming a second electrode layer on the first capacitor dielectric layer in the first capacitor region; and
forming one or more capacitor stacks in the first capacitor region after the second electrode layer is formed, wherein each of the capacitor stacks comprises a second capacitor dielectric layer and a third electrode layer located on the second capacitor dielectric layer, and projection overlay regions exist between the third electrode layer and the second electrode layer and between adjacent third electrode layers;
wherein one or more second capacitor dielectric layers are further formed on the first capacitor dielectric layer in the second capacitor region; and a third electrode layer at a top of the capacitor stack is used as a top electrode layer, the top electrode layer is further formed on the one or more second capacitor dielectric layers in the second capacitor region, and a projection overlay region exists between the top electrode layer and the first electrode layer.

13. The method according to claim 12, wherein a number of the capacitor stacks is one.

14. The method according to claim 12, wherein:
in the step of forming the one or more capacitor stacks in the first capacitor region, along a direction of a surface normal of the substrate, a direction in which the first electrode layer points to the second electrode layer is a vertical direction, and along the vertical direction, the third electrode layers in the one or more capacitor stacks comprise: odd-numbered third electrode layers and even-numbered third electrode layers; and
the method further comprises:
after the one or more capacitor stacks are formed, forming a first conductive plug, which is electrically connected to the first electrode layer and the odd-numbered third electrode layers, in the first capacitor region; and
forming a second conductive plug in the first capacitor region, wherein the second conductive plug is electrically connected to the second electrode layer, or the second conductive plug is electrically connected to the second electrode layer and the even-numbered third electrode layers.

15. The method according to claim 14, wherein:
in the step of forming the second electrode layer, the second electrode layer exposes a part of a top of the first electrode layer, and the part of the top of the first electrode layer exposed by the second electrode layer is used as a first connection region; the second electrode layer is further located on the substrate on a side of the first electrode layer, and the part of the second electrode layer located on the substrate on the side of the first electrode layer is used as a second connection region;
in the step of forming the one or more capacitor stacks, in the first capacitor region, the odd-numbered third electrode layers expose the second connection region and are further located in the first connection region; the even-numbered third electrode layers cover the second connection region and further expose the first connection region;
in the step of forming the first conductive plug: in the first capacitor region, the first conductive plug is formed in the first connection region, the first conductive plug runs through the odd-numbered third electrode layers and contacts the first electrode layer, and a side wall of the first conductive plug contacts the odd-numbered third electrode layers; and
in the step of forming the second conductive plug: in the first capacitor region, the second conductive plug is formed in the second connection region, the second conductive plug contacts the second electrode layer, or the second conductive plug runs through the even-numbered third electrode layers and contacts the second electrode layer, and a side wall of the second conductive plug contacts the even-numbered third electrode layers.

16. The method according to claim 15, wherein:
in the step of providing the substrate, the substrate comprises a device structure layer and a back-end-of-line interconnect layer located on the device structure layer and electrically connected to the device structure layer, the back-end-of-line interconnect layer comprises a bottom dielectric layer and one or more metal layers located in the bottom dielectric layer, and the metal layers located at a top are used as top metal layers;
in the step of forming the first conductive plug, in the first capacitor region, the first conductive plug further runs through the first electrode layer and contacts the top metal layers in the first connection region; and
in the step of forming the second conductive plug, in the first capacitor region, the second conductive plug further runs through the second electrode layer and contacts the top metal layers in the second connection region.

17. The method according to claim 12, further comprising:
after the one or more capacitor stacks are formed, forming a third conductive plug, which is electrically connected to the first electrode layer, in the second capacitor region; and
forming a fourth conductive plug, which is electrically connected to the top electrode layer, in the second capacitor region.

18. The method according to claim 17, wherein in the step of forming the top electrode layer, the top electrode layer exposes a part of a top of the first electrode layer, and the part of the top of the first electrode layer exposed by the top electrode layer is used as a third connection region; the top electrode layer is further located on the substrate on a side of the first electrode layer, and the part of the top electrode layer located on the substrate on the side of the first electrode layer is used as a fourth connection region;
the step of forming the third conductive plug comprises: in the second capacitor region, forming the third conductive plug contacting the first electrode layer in the third connection region; and
the step of forming the fourth conductive plug comprises: in the second capacitor region, forming the fourth conductive plug contacting the top electrode layer in the fourth connection region.

19. The method according to claim 18, wherein:
in the step of providing the substrate, the substrate comprises a device structure layer and a back-end-of-line interconnect layer located on the device structure layer and electrically connected to the device structure layer, the back-end-of-line interconnect layer comprises a bottom dielectric layer and one or more metal layers located in the bottom dielectric layer, and the metal layers located at a top are used as top metal layers;
in the step of forming the third conductive plug, in the second capacitor region, the third conductive plug further runs through the first electrode layer and contacts the top metal layers in the third connection region; and
in the step of forming the fourth conductive plug, in the second capacitor region, the fourth conductive plug further runs through the second electrode layer and contacts the top metal layers in the fourth connection region.
